(19) United States
(12) Patent Application Publication
(10) Pub. No.: US 2009/0237276 A1
(43) Pub. Date: Sep. 24, 2009

(54) COMPUTER APPARATUS AND THE FUNCTION ACTIVATING METHOD THEREOF

(75) Inventor: Hsin-Chi Lai, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INVENTEC CORPORATION, Taipei City (TW)

(21) Appl. No.: 12/052,744

(22) Filed: Mar. 21, 2008

(51) Int. Cl. H03M 11/00

(52) U.S. Cl. 341/26

(57) ABSTRACT

A computer apparatus is provided, which includes a function key, controller, basic input/output system (BIOS) unit and operating system (OS) unit. The function key is used for activating a predetermined function of the computer apparatus and outputting a control signal when the function key is enabled. The controller is used for receiving the control signal and sending a corresponding function code and a scan code. The BIOS unit is used for receiving and storing the function code. The OS unit has an application program. The OS unit receives the scan code, receives the function code based on the scan code and executes a corresponding process based on the function code.

### BACKGROUND OF THE INVENTION

1. Field of the Invention

The present invention relates to a computer apparatus and method, and more particularly to an apparatus and method of activating a function of computer apparatus by a keyboard.

2. Description of Related Art

Today, with improving technology, personal computers have become important data processing equipments in people' daily life. Especially notebooks, they provide high portability so that information can be carried around and processed, which is a powerful tools for people for business nowadays.

With people's increasing demands on functions of the notebook, functions affiliated to the notebook are also increased. For users' convenient operation, most devices for activating these functions are Fn keys disposed on the keyboard or other separately added function keys. However, all of the keys on the keyboard notify the computer to activate associated functions by sending corresponding keyboard scan codes. Therefore, the more function keys are increased, the more scan codes are generated. With so many scan codes in different versions of operating systems, conflicts with operating systems are occurred.

Based on the above, in the same computer, if different versions of operating systems are installed, scan codes generated by certain function keys may not work normally because of conflicts with the operating system, and thereby many functions may fail.

### SUMMARY OF THE INVENTION

In view of the foregoing, the present invention provides a computer apparatus and a method used for activating a function of the computer apparatus by a keyboard, by which only one scan code is required for a plurality of function keys to activate corresponding processes.

The present invention provides a computer apparatus including a function key, a controller, a basic input/output system (BIOS) unit and an operating system (OS) unit. The function key is used for activating a predetermined function of the computer apparatus and outputting a control signal when the function key is enabled. The controller is coupled to the function key and used for sending a corresponding function code based on the control signal and a scan code. In addition, the BIOS unit is coupled to the controller and serves as receiving and storing the function code. The OS unit having an application program is coupled to the controller and the BIOS unit. The OS unit is used for receiving the scan code, receiving the function code based on the scan code and executing a corresponding process based on the function code.

Furthermore, in one embodiment of the present invention, the corresponding process is executed by pressing the function key.

In one embodiment of the present invention, the OS unit further receives the function code upon the scan code being received by the OS unit.

The present invention provides a function activating method of a computer apparatus having a function key. The method includes the following steps. First, a pressing status of the function key is detected. Then, a corresponding function code and a scan code are generated according to the pressing status. Finally, the function code is received based on the scan code, and a corresponding process is executed based on the received function code.

The present adopts converting the control signal sent by the function key into the function code and storing the function code in advance so that the function code is separately read by an application program module. Hence, a plurality of function keys is used without using many scan codes so as to avoid conflicts with the operating system.

In order to make the aforementioned and other objects, features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic view of a computer apparatus according to one embodiment of the present invention.

FIG. 2 illustrates a schematic view of a computer apparatus according to another embodiment of the present invention.

FIG. 3 illustrates a schematic view of a function activating method of a computer apparatus according to one embodiment of the present invention.

FIG. 4 illustrates a schematic view of a function activating method of a computer apparatus according to another embodiment of the present invention.

### DESCRIPTION OF EMBODIMENTS

Hereinafter, a computer apparatus and a function activating method thereof according to preferred embodiments of the present invention will be described with reference to the relative drawings.

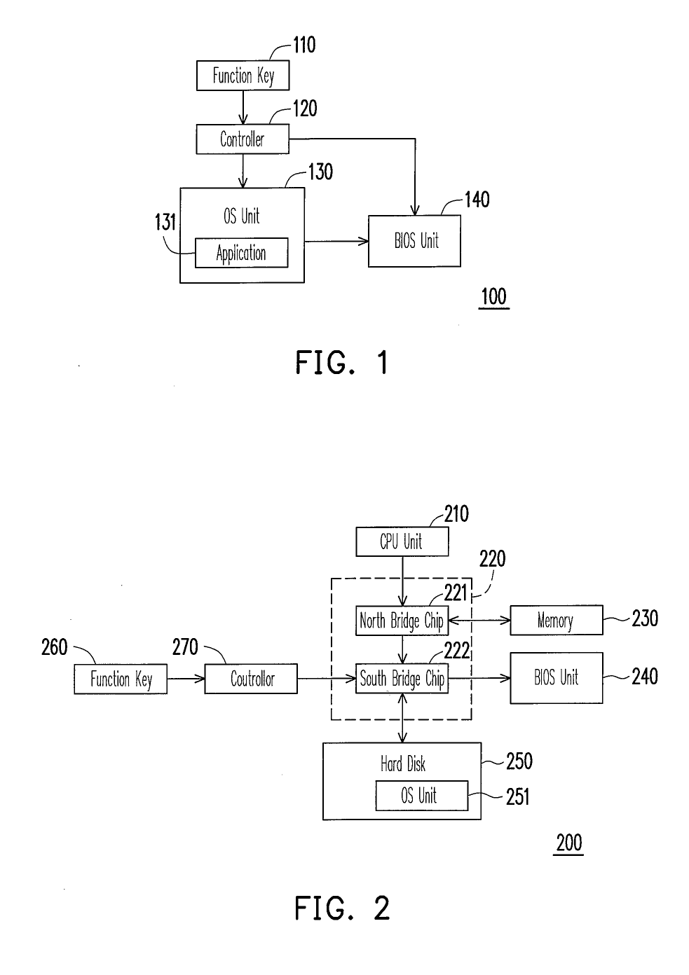

Referring to FIG. 1, it illustrates a schematic view of a computer apparatus according to one embodiment of the present invention. A computer apparatus 100 in the present embodiment includes a function key 110, a controller 120, an operating system (OS) unit 130 with an application program 131 built therein and a basic input/output system (BIOS) unit 140. The function key 110 includes a plurality of Fn keys (e.g. F1 through F12 keys) or other additional keys thereon. These Fn keys usually represent a function respectively, for example, key F1 can be used for adjusting contrast of monitors, F2 can be used for adjusting brightness of monitors, and additional function keys are separately provided additional keys when Fn keys are not sufficient.

When a user wants to use a predetermined function of the computer apparatus 100, he/she presses a corresponding function key 110. Meanwhile, the controller 120 receives a control signal generated while the function key 110 is pressed and sends a pre-set scan code to the OS unit 130. In addition, the controller 120 generates a function code in correspondence to the pressed function key 110. Then, the function code is sent to and stored in the BIOS unit 140. The scan code is used for notifying the latter OS unit 130 to execute messages of the application program therein, and the scan code is not used by most built-in functions of the operation system. The function code is a code of the application program to be executed, which can be identified by both the controller 120 and the OS unit 130.

When the scan code is received by the OS unit 130, it can be know that a function is to be activated. In the meantime, the OS unit 130 retrieves the function code from the BIOS unit 140. Thus, the OS unit 130 can acknowledge that the application program 130 is to be executed by the user and then activates such execution.

Herein, a specific example will be illustrated so that those with ordinary skills of the art may have further understanding and implement the present invention accordingly.

When a user wants to turn speakers up, he/she presses an Fn key (for example, F10) used for turning volume up. In the meantime, the detector 120 detects a control signal sent while the F10 key is pressed so that a function code (for example, 01) of turning volume up is generated and stored into the BIOS unit 140. Meanwhile, a scan code is generated to notify the OS unit 130 to execute the function of turning volume up. Upon receiving the scan code, the OS unit 130 retrieves the function code from the BOIS unit 140 and executes turning volume up according to the function code (01 in this example).

After that, when a user wants to turn the speakers down, he/she presses an Fn key (for example, F9) used for turning volume down. In the meantime, the detector 120 detects a control signal sent while the F9 key is pressed so that a function code (for example, 02) of turning volume down is generated and stored into the BIOS unit 140. Meanwhile, a scan code is generated to notify the OS unit 130 to execute the function of turning volume down. Upon receiving the scan code, the OS unit 130 retrieves the function code from the BOIS unit 140 and executes turning volume down according to the function code (02 in this example).

It is apparent from the example illustrating actions of the computer apparatus 100 as described above that only one scan code is used by the controller 120 to accomplish a variety of functions. Thereby, conflicts with built-in functions of the OS caused from the keyboard having too many scan codes can be effectively eliminated.

Referring to FIG. 2, it illustrates a schematic view of a computer apparatus according to one embodiment of the present invention. In FIG. 2, a computer apparatus 200 is illustrated, which includes a central processing unit (CPU) 210, a chip set 220, a memory 230, a BOIS unit 240, a hard disk 250, a function key 260 and a controller 270. The chip set 220 is consisted of a north bridge chip 221 and a south bridge chip 222. An OS unit 251 is stored in the hard disk 250.

When a user wants to use a predetermined function of the computer apparatus 200, he/she presses the function key 260. The function key 260 is usually disposed on a keyboard (not shown). Of course, it can also be disposed on other peripherals (e.g. a mouse or a touch-screen monitor) of the computer apparatus 200. The controller 270 detects a control signal sent while the function key 260 is pressed so that a scan code is generated and sent to the south bridge chip 222. Then, the scan code is sent to OS unit 251 by the south bridge chip 222. Meanwhile, a function code is generated and stored in the BIOS unit 240. After the scan code is received by the OS unit 251, the BIOS unit 240 reads the function code stored therein just now and executes an associated application program based on the function code.

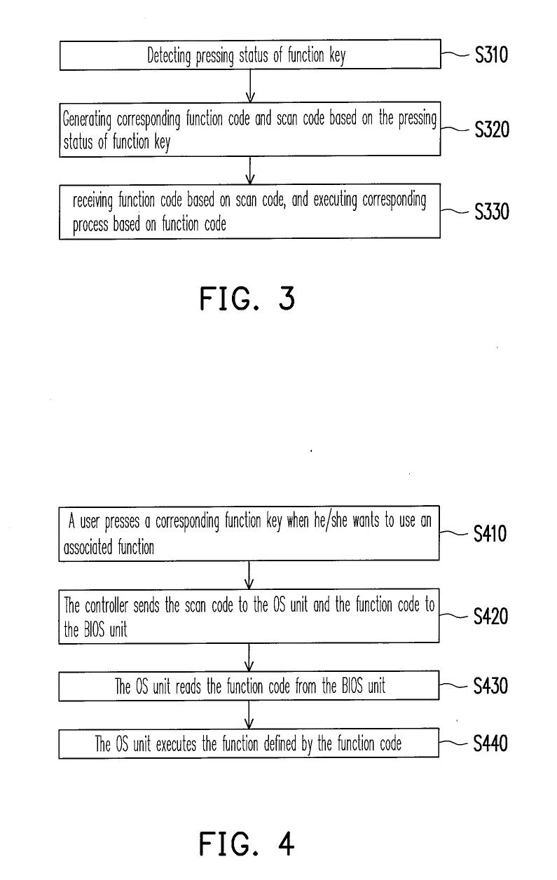

Referring to FIG. 3, it illustrates a schematic view of a function activating method of a computer apparatus according to one embodiment of the present invention. The method includes the following steps. First, a pressing status is detected (S310). When the function key being pressed is detected, a corresponding function code and a fixed scan code are generated (S320). The generated function code is stored. Finally, the function code is received based on the scan code, and then a corresponding process is executed based on the received function code (S330).

As for the function activating method of the computer apparatus, an embodiment thereof will be further described so that those with ordinary skills of the art can understand more about the present invention.

Referring to FIG. 3 (together with FIG. 1), it illustrates a schematic view of a function activating method of a computer apparatus according to another embodiment of the present invention. The present embodiment includes steps as follows. When a user wants to use an associated function, he/she presses a corresponding function key on the keyboard 110 (S410). In the meantime, the controller 120 detects that a function key is pressed, sends a scan code to the OS unit 130 and sends a function code to the BIOS unit 140 (S420). Upon the application module 130 receiving the scan code, the BIOS unit 140 reads the function code (S430). The application 131 built in the OS unit 130 executes a function defined by the function code (S440).

In view of the foregoing, the present invention utilizes the controller in the computer apparatus to receive the scan code of the keyboard and converts the scan code into a fixed scan code and a corresponding function code so as to execute the function activating. As a result, scan codes of the keyboard actually sent to the OS and the application module requires only one. Hence, the scan code can be effectively prevented from being increased by increasing function codes. Thus, the problem of the function codes conflicting with the OS can be eliminated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A computer apparatus, comprising:
a function key, used for activating a predetermined function of the computer apparatus and outputting a control signal when the function key is enabled;
a controller, coupled to the function key and used for sending a corresponding scan code and a function code based on the function key being pressed;
a basic input/output system (BIOS) unit, coupled to the controller and used for receiving and storing the function code; and
an operating system (OS) unit, having an application program, which is coupled to the controller and the BIOS unit and used for receiving the scan code so as to retrieve the function code from the BIOS unit based on the scan code and execute a corresponding process based on the function code.

2. The computer apparatus as claimed in claim 1, wherein the corresponding process is executed by pressing the function key.

3. The computer apparatus as claimed in claim 1, wherein the OS unit further receives the function code upon the scan code being received thereby.

4. A function activating method of a computer apparatus having a function key, comprising:
detecting whether or not the function key is pressed;
generating a corresponding function code and a scan code based on the status of the function key; and
retrieving the function code from a BIOS of the computer apparatus based on the scan code and executing a corresponding process based on the function code.

5. The function activating method of a computer apparatus as claimed in claim 4, wherein the step of generating the function code based on the pressing status and the scan code further comprises storing the function code.

6. The function activating method of a computer apparatus as claimed in claim 4, wherein the corresponding process is executed by pressing the function key.

7. The function activating method of a computer apparatus as claimed in claim 4, wherein the step of receiving the function code based on the scan code further comprises receiving the function code upon the scan code being received.
